(19) United States
(12) Patent Application Publication
(10) Pub. No.: US 2007/0085619 A1
(43) Pub. Date: Apr. 19, 2007

(54) Voltage-controlled oscillator, associated temperature detecting unit, and integrated circuit

(75) Inventor: Reinhard Reimann, Heilbronn (DE)

Correspondence Address: MCGRATH, GEISSLER, OLDS & RICHARDSON, PLLC, P.O. BOX 1364, FAIRFAX, VA, 22038-1364, US

(73) Assignee: ATMEL Germany GmbH

(21) Appl. No.: 11/513,097

(22) Filed: Aug. 31, 2006

(30) Foreign Application Priority Data
Sep. 1, 2005 (DE) DE 102005042705
Dec. 8, 2005 (DE) DE 102005059488

(51) Int. Cl. H03B 5/12

(52) U.S. Cl. 331/177 V

(57) ABSTRACT

A voltage-controlled oscillator, associated temperature detecting unit, and integrated circuit is disclosed. The voltage-controlled oscillator comprises a frequency drift compensation unit, which compensates for a frequency drift of the oscillator and supplies a compensation signal to a component having a voltage-controlled capacitance.

This nonprovisional application claims priority under 35 U.S.C. § 119(a) on German Patent Application Nos. DE 102005042705 and DE 102005059488, which were filed in Germany on Sep. 1, 2005. and Dec. 8, 2005, respectively, and which are both herein incorporated by reference.

### BACKGROUND OF THE INVENTION

1. Field of the Invention

The present invention relates to a voltage-controlled oscillator according to the preamble of claim 1, an associated temperature detecting unit, and an integrated circuit.

2. Description of the Background Art

Voltage-controlled oscillators typically comprise a resonant circuit of a voltage-controllable capacitor and an inductor, and an undamping circuit, which compensates for damping losses of the resonant circuit due to ohmic losses in the resonant circuit components.

The application of a control voltage or a frequency control signal to the voltage-controllable capacitor, typically one or more so-called capacitor diodes or varactors, alters their capacitance value, as a result of which the resonance or operating frequency of the resonant circuit changes accordingly.

When the operating conditions of the voltage-controlled oscillator change, for example, its operating temperature, typically an undesirable frequency change or a frequency drift of the oscillator operating frequency occurs. If the voltage-controlled oscillator is part of a phase-locked loop (PLL), the frequency control signal is typically generated by the PLL in such a way that the frequency drift is corrected.

When the voltage-controlled oscillator and the PLL are part of a transmitter-receiver or a transceiver, the PLL can be deactivated during a transmit operation of the transceiver in a so-called “open loop” mode; i.e., the frequency control signal generated by the PLL remains constant during the transmit operation. If a frequency drift occurs during the transmit operation, for example, because of heating, this is therefore no longer corrected by the PLL.

In German patent application No. 10 2004 020 975.8, which corresponds to U.S. Publication No. 2005237124, and which is incorporated herein by reference, a voltage-controllable compensation capacitor, which is provided exclusively for this purpose and which is supplied with a compensation signal by a frequency drift compensation unit, is used for compensating this type of frequency drift in the open-loop mode. The operating frequency setting of the oscillator is realized by a voltage-controllable operating capacitor, which is supplied with a frequency control signal by the PLL. The compensation capacitor or the frequency drift compensation unit is used here only for compensating frequency drift effects in the open loop mode.

To achieve the broadest possible compensation range of frequencies, the compensation capacitor should be selected relatively large. Because the compensation capacitor is used only in the open loop mode, however, i.e., does not contribute to the settable frequency range, it should be dimensioned relatively small in comparison with the operating capacitor. As a compromise solution, for example, the voltage range of the compensation signal can be selected as relatively large, which results in a correspondingly larger frequency setting range for the compensation signal. This can result, however, in phase jitter. To reduce the phase jitter, a so-called blocking capacitor can be used, which forms an RC filter in conjunction with a resistor and is used for filtering the compensation signal, which results in a reduction of the phase jitter caused by the compensation signal. Because relatively high capacitance values are necessary for this, however, it may be impossible to integrate the filter capacitor into an integrated circuit, into which the oscillator is integrated if necessary.

A major cause of the frequency drift is temperature changes in the oscillator. Temperature changes can be caused, for example, by neighboring circuit parts which change their operating status. In a transmitter-receiver or transceiver, for example, activation of the transmit operation and an associated activation of a power amplifier can cause the heating of the oscillator used in the transceiver.

Bipolar semiconductors can be used as temperature detectors or temperature sensors for detecting or measuring the temperature in integrated circuits. The voltage declining at the bipolar semiconductors, which is a measure of the temperature to be measured, is typically compared with a constant reference voltage in a differential amplifier. The output voltage range of the differential amplifier or a dynamic range must be adjusted to the conventional temperature range of the integrated circuit, i.e., to a temperature range of, for example, −40° C. to +85° C. Furthermore, in selecting the dynamic range, possible component tolerances, particularly the bipolar semiconductors used as the temperature sensors and the reference voltage, must be considered.

### SUMMARY OF THE INVENTION

It is therefore an object of the invention to provide a voltage-controlled oscillator, a temperature detecting unit, and an integrated circuit, which make possible an effective, precise, and simple compensation of an especially temperature-induced frequency drift in the oscillator.

The voltage-controlled oscillator comprises at least one component with a voltage-controllable capacitor, which is supplied with a frequency control signal to set an oscillator operating frequency, and a frequency drift compensation unit, which supplies the component with a compensation signal to compensate for the oscillator frequency drift. According to the invention, the compensation capacitor and operating capacitor coincide, i.e., a separate compensation capacitor is not provided. Consequently, the complete capacitance value is available both for operating frequency setting and also for compensating the frequency drift. Of course, a plurality of components, for example, connected in parallel, with a voltage-controllable capacitor can be provided to form the operating capacitor. The frequency control signal is typically generated by a PLL. The frequency drift compensation unit compensates hereby for frequency drift effects, which occur with an opened PLL control loop in the open loop mode, for example, during the transmit operation of a transceiver, by a suitable generation or setting of the compensation signal.

In a further embodiment, the frequency control signal can be applied to a first terminal of the component and the compensation signal to a second terminal of the component. In this way, a differential signal can form between the frequency control signal, for example, in the form of a control voltage, and the compensation signal, for example, in the form of a compensation voltage, whereby the resulting voltage difference determines the capacitance value of the voltage-controllable capacitor. Both the operating frequency can be set simply in this way, and the frequency compensation can be effected.

In a further embodiment, the component can be a capacitance diode. Capacitance diodes enable a simple and cost-effective voltage-dependent capacitance setting.

In a further embodiment, a temperature detecting unit, coupled to the frequency drift compensation unit, can be provided to detect an oscillator operating temperature, whereby the frequency drift compensation unit is formed in such a way that it generates the compensation signal as a function of the operating temperature. A temperature-induced frequency drift can be effectively compensated in this manner.

In a further embodiment, a first and a second component with a voltage-controllable capacitor, a first oscillator coil and a second oscillator coil, each of which is connected to a terminal with a reference voltage, and a first coupling capacitor and a second coupling capacitor are provided, whereby the first coupling capacitor, the first component, the second component, and the second coupling capacitor are looped in series between the terminals, not connected to the reference voltage, of the first and second oscillator coil, the frequency control signal is applied to a connection point of the first and second component, and the compensation signal is applied to the terminal, opposite the connection point, of the first and second component. The first and second components are preferably capacitance diodes. The described wiring makes it possible in a simple way to generate a voltage at the voltage-controllable components, which results from a voltage difference of the frequency control signal and the compensation signal. An operating frequency can therefore be set in a simple manner by suitable selection of the frequency control signal and the compensation signal, whereby a frequency drift is compensated by changing the compensation signal.

Preferably, a first decoupling resistor, which is looped in between the compensation signal and the terminal, opposite the connection point, of the first component and a second decoupling resistor are provided, which is looped in between the compensation signal and the terminal, opposite the connection point, of the second component. The decoupling resistors cause a decoupling of high-frequency signals and a DC coupling to the compensation voltage.

An undamping unit is provided in a further embodiment. The undamping unit compensates for damping losses of the resonant circuit due to ohmic losses.

In a further embodiment, the operating frequency is in the range of 2 GHz to 7 GHz. Preferably the frequency is 5.8 GHz.

The temperature detecting unit of the invention for a voltage-controlled oscillator comprises a temperature sensor, a differential amplifier, whereby a first terminal of the differential amplifier is connected to the temperature sensor and a temperature signal is present at an output of the differential amplifier, a buffer unit, whereby an input of the buffer unit is connected to the temperature sensor and an output to a second terminal of the differential amplifier, and a control unit, which controls the buffer unit in such a way that a temperature sensor value is stored temporarily at the start of a measuring interval. This makes possible a differential temperature measurement between two temperature values, for example, a value at the start of the measuring interval and a value at the end of the measuring interval, as a result of which an output voltage range or a dynamic range of the differential amplifier need not be adapted to the typical entire temperature range of the integrated circuit, i.e., to a temperature range of, for example, −40° C. to +85° C., but only to the temperature differences typically arising within the measuring interval. Furthermore, because of the differential temperature measurement, possible component tolerances, particularly of the bipolar semiconductors used as temperature sensors and the reference voltage, are automatically compensated. Overall, thus, an amplification of the differential amplifier can be increased considerably, as a result of which a measurement resolution improves substantially, i.e., it is possible to detect much lower temperature differences. Preferably, the temperature detecting unit of the invention can be combined with the voltage-controlled oscillator of the invention.

In a further embodiment, the temperature sensor comprises a bipolar semiconductor. Bipolar semiconductors make possible a cost-effective realization of a temperature sensor, particularly in integrated circuits.

In a further embodiment, the temperature sensor comprises at least one p-n diode. Here, a so-called flux voltage of the p-n diode is used as the temperature indicator. A plurality of p-n diodes can be connected in series, as a result of which the specific flux voltages are added.

In a further embodiment, the control unit can be formed in such a way that it causes the temporary storage of the temperature sensor value depending on the operating state. This makes possible a differential temperature measurement between two temperatures, each of which belong to points in time between which typically considerable heating and/or rapid cooling must be anticipated. For example, this can be the case during the activation of a power amplifier during a transmit process of a transceiver. In this case, shortly before the transmission, i.e., the activation of the power amplifier, at the start of the measuring interval, a temperature sensor value is temporarily stored and then a temperature difference between an actual temperature or an actual temperature sensor value and the temporarily stored temperature sensor value is generated. This makes possible a very high temperature resolution in operating states in which a considerable temperature change occurs, whereby the temperature change within the measuring interval is relatively small compared with the entire temperature range.

The integrated circuit of the invention comprises a voltage-controlled oscillator of the invention and/or a temperature detecting unit of the invention. Preferably, the integrated circuit forms an ISM transceiver. The ISM band (industrial, scientific, and medical band) is a frequency range for communication devices in industry, science, and medicine. A frequency selection for the ISM bands is not consistently regulated worldwide. Thus, for example, there are ISM bands in the frequency range of 902 MHz-928 MHz, 2,400 MHz-2,483.5 MHz, and 5,800 MHz, and only the 2.4-GHz band is free worldwide.

Further scope of applicability of the present invention will become apparent from the detailed description given hereinafter. However, it should be understood that the detailed description and specific examples, while indicating preferred embodiments of the invention, are given by way of illustration only, since various changes and modifications within the spirit and scope of the invention will become apparent to those skilled in the art from this detailed description.

### BRIEF DESCRIPTION OF THE DRAWINGS

The present invention will become more fully understood from the detailed description given hereinbelow and the accompanying drawings which are given by way of illustration only, and thus, are not limitive of the present invention, and wherein:

FIG. 1 shows a basic circuit diagram of a voltage-controlled oscillator according to an embodiment of the present invention;

FIG. 2 is a detailed circuit diagram of a voltage-controlled oscillator of the invention with a frequency drift compensation unit and a temperature detecting unit, coupled thereto, to detect an oscillator operating temperature;

FIG. 3 is a detailed circuit diagram of a frequency control unit FS of FIG. 2; and

FIG. 4 is a detailed circuit diagram of a temperature detecting unit of FIG. 2.

### DETAILED DESCRIPTION

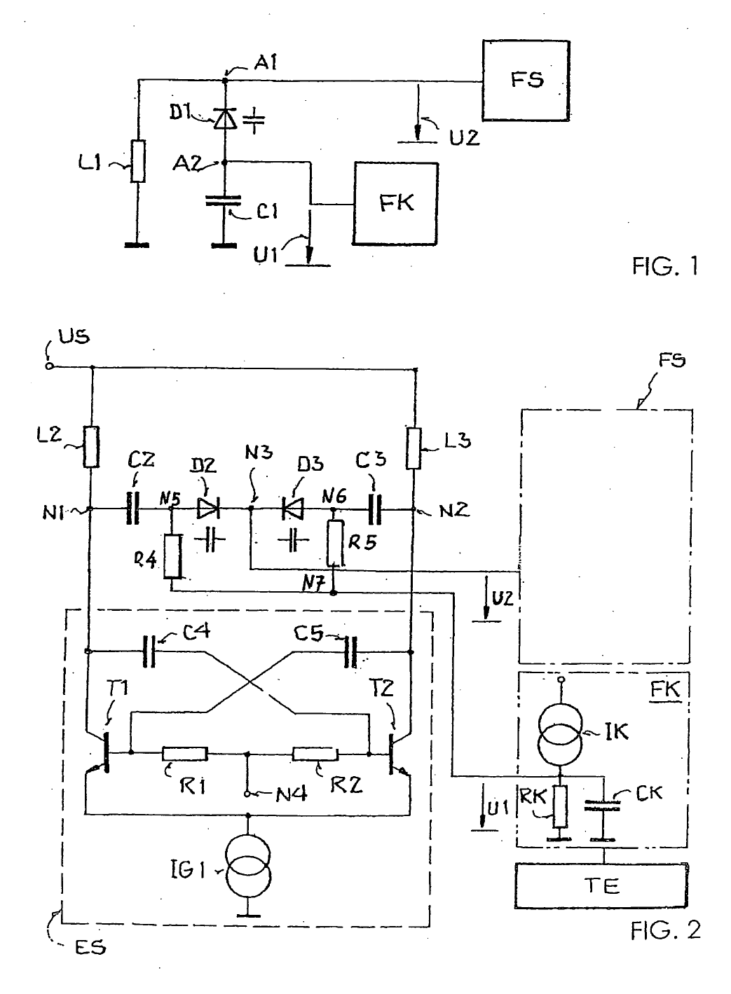

FIG. 1 shows a basic circuit diagram of a voltage-controlled oscillator of the invention with a component with a voltage-controlled capacitor in the form of a varactor diode D1, a coil L1, whereby the varactor diode D1 and the coil L1 form a resonant circuit, with a decoupling capacitor C1, and a frequency drift compensation unit FK, which to compensate for a frequency drift of the oscillator, for example, due to temperature variations, supplies the varactor diode with a compensation signal in the form of a compensating voltage U1. Furthermore, a frequency control unit FS is provided, which the varactor diode D1 supplies with a frequency control signal in the form of a frequency control voltage U2 to set the oscillator operating frequency. The frequency control unit FS is part of a conventional phase-locked loop (PLL), which is not shown further. The shown circuit arrangement can be integrated into an ISM transceiver, which is not shown. The circuit diagram shown in FIG. 1 is used here only to illustrate the principle of the invention.

The varactor diode D1 is looped in series with the decoupling capacitor C1 between the frequency control voltage U2 and a reference voltage in the form of a ground voltage. The coil L1 is also looped in between the frequency control voltage U2 and the ground voltage.

The frequency control voltage U2 is applied to a first terminal A1 of the varactor diode D1 and the compensation voltage U1 to a second terminal A2 of the varactor diode D1. The resulting voltage at the varactor diode D1, which determines its capacitance value, thus results from the voltage difference between the frequency control voltage U2 and the compensation voltage U1.

To set the oscillator operating frequency, the frequency control voltage U2 generated by the PLL or the frequency control unit FS is basically used, which is readjusted outside of a transmit operation of the ISM transceiver by the PLL in such a way that a desired constant operating frequency arises. During the transmit operation of the ISM transceiver, the PLL control loop is opened in the open loop mode, i.e., the frequency control voltage U2 remains constant. Frequency drift effects, for example, due to temperature changes, are compensated in the open loop mode by appropriate setting of the compensation voltage U1 by the frequency drift compensation unit FK.

The varactor diode D1 of the oscillator is thus used both for setting the operating frequency and also for frequency drift compensation. This makes possible a large frequency compensation range, whereby the frequency range that can be set by the frequency control voltage U2 is not reduced by this.

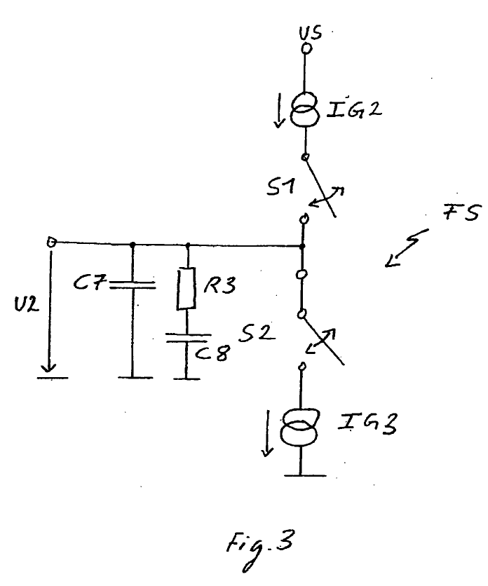

FIG. 2 shows a detailed circuit diagram of a voltage-controlled oscillator of the invention with the frequency drift compensation unit FK of FIG. 1, a temperature detecting unit TE, coupled thereto, for detecting the oscillator operating temperature, and the frequency control unit FS of FIG. 1 for setting the oscillator operating frequency. The shown circuit arrangement is integrated into an ISM transceiver, which is not shown.

The oscillator comprises furthermore a first varactor diode D2 and a second varactor diode D3, a first oscillator coil L2 and a second oscillator coil L3, each of which is connected to a terminal with a supply voltage US, a first coupling capacitor C2 and a second coupling capacitor C3, and a first decoupling resistor R4 and a second decoupling resistor R5, whereby the first coupling capacitor C2, the first varactor diode D2, the second varactor diode D3, and the second coupling capacitor C3 are looped in series between the terminals, not connected to the supply voltage US, of the first and the second oscillator coil L2 or L3. The specific cathodes of varactor diodes D2 and D3 are connected to a connecting node N3. The specific anodes of varactor diodes D2 and D3 are connected to one another via decoupling resistors R4 and R5. Decoupling resistors R4 and R5 cause a decoupling of high-frequency signals, which are applied at nodes N5 and N6 or at the specific anodes of varactor diodes D2 and D3, and a DC coupling of nodes N5 and N6 to compensation voltage U1, which is applied at a connecting node N7 of decoupling resistors R4 and R5.

An output signal of the oscillator is applied at a connecting node N1 of first oscillator coil L2 and of first coupling capacitor C2 or at a connecting node N2 of second oscillator coil L3 and of second coupling capacitor C3.

An undamping unit in the form of an undamping circuit ES compensates for damping losses of the resonant circuit because of ohmic losses in the resonant circuit components. The undamping circuit is connected to node N1 and node N2. It is constructed in a conventional manner and comprises a DC source IG1, transistors T1 and T2, capacitors C4 and C5, and resistors R1 and R2. The collector-emitter section of transistor T1 is looped in between connecting node N1 and DC source IG1 and the collector-emitter section of transistor T2 between connecting node N2 and DC source IG1. The resistors R1 and R2 are looped in series between the specific base terminals of transistors T1 and T2. Capacitor C4 is looped in between node N1 and the base terminal of transistor T2, and capacitor C5 is looped in between node N2 and the base terminal of transistor T1, as a result of which a cross-over, AC-wise coupling of the base terminals with nodes N1 or N2 is produced. A connecting node N4 between resistors R1 and R2 for setting the operating point can be supplied with a DC voltage or a direct current (not shown).

The undamping circuit ES consequently represents an AC source with a cross coupling of the specific collector terminals and the base terminals of transistors T1 and T2, which form a differential transistor pair, which supplies energy in-phase to the resonant circuit, formed from varactor diodes D2 and D3 and oscillator coils L2 and L3, via nodes N1 and N2 and thereby compensates for the damping losses of the resonant circuit. Transistors T1 and T2, shown in FIG. 2, are realized as bipolar transistors. Of course, transistors T1 and T2 can also be realized as MOS transistors.

The frequency control unit FS generates the frequency control signal in the form of the frequency control voltage U2 to set the oscillator operating frequency, and the frequency drift compensation unit FK generates the compensation signal in the form of the compensation voltage U1 to compensate for frequency drift effects in the open loop mode. The frequency control voltage U2 is applied to node N3 as the connection point of varactor diodes D2 and D3. The compensation voltage U1 is applied via decoupling resistors R4 and R5 at the terminal N5 or N6, opposite to the connection point or node N3, of varactors D2 or D3. A voltage difference determining a capacitance value of the varactors D2 or D3 can be set in this way by suitable selection of the level of voltages U2 or U1.

FIG. 3 shows a detailed circuit diagram of the frequency control unit FS of FIG. 2. The frequency control unit FS comprises a charging DC source IG2, a discharging DC source IG3, a first switch S1, a second switch S2, and a loop filter in the form of a resistor R3 and two capacitors C7 and C8. The current sources IG2 and IG3 and the switches S1 and S2 are looped in series between the supply voltage US and ground. The frequency control voltage U2 is present at a connection point of switches S1 and S2. Capacitor C7 is looped in between the frequency control voltage U2 and ground. Resistor R3 and capacitor C8 are looped in series between the frequency control voltage U2 and ground.

To produce a change in the frequency control voltage U2, capacitors C7 and C8 are charged or discharged depending on the switch position of switches S1 and S2. This causes a continuous increase or decrease in the frequency control voltage U2. When both switches S1 and S2 are opened, the frequency control voltage U2 remains constant.

During the transmit operation of the transceiver in the open loop mode of the PLL, both switches S1 and S2 are opened; i.e., the frequency control voltage U2 remains constant. Because no compensation or correction of frequency drift effects by the PLL can occur in this mode or state, these are compensated by the compensation voltage U1 supplied by the frequency drift compensation unit FK. A change in the compensation voltage U1 causes a change in the active control voltage applied at the varactor diodes D2 and D3, which results from the voltage difference of the frequency control voltage U2 and the compensation voltage U1. This effective control voltage determines the capacitance value of the varactor diodes D2 and D3.

The compensation voltage U1 supplied by the frequency drift compensation unit FK is hereby adjusted continuously depending on the oscillator temperature determined by the temperature detecting unit TE. In addition to temperature, other parameters can also influence the compensation voltage U1. The compensation voltage U1 is thus used to compensate for drift effects.

A controllable current source IK, which supplies a current dependent on the temperature determined by the temperature detecting unit TE, a resistor RK, and a blocking capacitor CK, can be provided to generate the compensation voltage U1, for example, in the frequency drift compensation unit FK. The current supplied by the current source IK is converted by the resistor RK into a proportional compensation voltage U1. The blocking capacitor CK is used to filter the voltage U1 in order to reduce the phase jitter of the generated oscillator signal. The resistor RK and the blocking capacitor CK can also be realized in each case externally or in a combination of externally/internally.

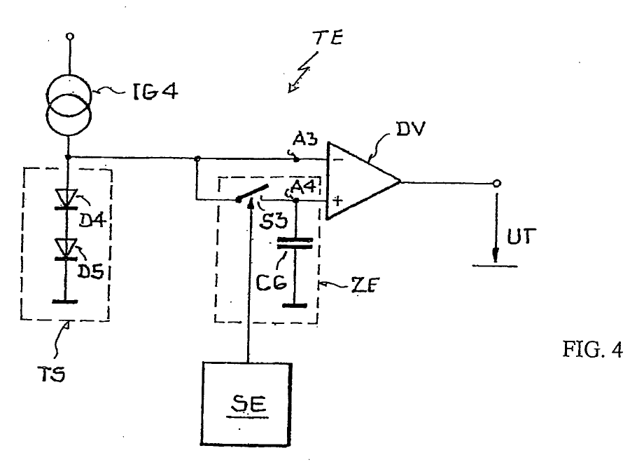

FIG. 4 shows a detailed circuit diagram of the temperature detecting unit TE of FIG. 2. The temperature detecting unit TE comprises a temperature sensor TS in the form of two p-n diodes D4 and D5 connected in series, a DC source IG4, which supplies the p-n diodes D4 and D5 with a constant measuring current, a differential amplifier DV, whereby a first terminal A3 of the differential amplifier is connected to the temperature sensor TS and the temperature signal UT is applied at the output of the differential amplifier DV, a buffer unit ZE in the form of a storage capacitor C6, and a switch S3, whereby an input of the buffer unit ZE or a terminal of the switch S3 is connected to the temperature sensor TS and an output of the buffer unit ZE or the other terminal of switch S3 and storage capacitor C6 to a second terminal A4 of differential amplifier DV.

Furthermore, a control unit SE is provided, which controls the buffer unit ZE in such a way that a temperature sensor value is temporarily stored at the start of a measuring interval. To take over a temperature sensor value, the control unit SE controls switch S3 in such a way that this switch is closed. Storage capacitor C6 then charges to the voltage value applied at the temperature sensor TS or discharges to it. After a certain waiting time, which enables charging or discharging, switch S3 is again opened, as a result of which a voltage value applied at the storage capacitor C6 remains constant, i.e., is stored.

The voltage value at the temperature sensor TS results from the flow voltage of diodes D4 and D5, which is determined by their temperature or by the integrated circuit containing them.

The output signal UT of the differential amplifier DV is therefore a measure of the temperature difference between the actual temperature value and the temperature value stored in the buffer or its associated voltage.

By suitable control of switch S3 by the control unit SE, it is thus possible to resolve very small temperature changes over time intervals in which typically heating or cooling occurs. An amplification factor or a dynamic range of the differential amplifier can be set therefore in such a way that it corresponds to the temperature changes, for example, a maximum of 5 K, typically occurring in the temperature interval. When the temperature evaluation occurs as in conventional solutions over the entire possible temperature range (i.e., a constant reference voltage is applied at input A4 of the differential amplifier), the amplification must be reduced accordingly, because here a temperature range of, for example, about 120 K must be covered.

The output signal UT of the differential amplifier DV is used as the input signal of the frequency drift compensation unit FK, which depending on the signal accordingly adjusts the compensation voltage U1.

The indicated circuit arrangements can be integrated into an integrated circuit, which can have the function of the ISM transceiver.

The shown exemplary embodiments enable an effective, precise, and simple compensation of an especially temperature-induced frequency drift of the oscillator.

The invention being thus described, it will be obvious that the same may be varied in many ways. Such variations are not to be regarded as a departure from the spirit and scope of the invention, and all such modifications as would be obvious to one skilled in the art are to be included within the scope of the following claims.

What is claimed is:

1. A voltage-controlled oscillator comprising:
at least one component having a voltage controlled capacitance, which is supplied with a frequency control signal to set an oscillator operating frequency; and
a frequency drift compensation unit for providing the component with a compensation signal to compensate for oscillator frequency drift.

2. The voltage-controlled oscillator according to claim 1, wherein the frequency control signal is applied to a first terminal of the component and the compensation signal to a second terminal of the component.

3. The voltage-controlled oscillator according to claim 1, wherein the component is a capacitance diode.

4. The voltage-controlled oscillator according to claim 1, further comprising:
a temperature detecting unit coupled to the frequency drift compensation unit to detect an oscillator operating temperature,
wherein the frequency drift compensation unit generates the compensation signal as a function of the operating temperature.

5. The voltage-controlled oscillator according to claim 1, further comprising:
a first and a second component having a voltage-controlled capacitance;
a first oscillator coil and a second oscillator coil, each of which is connected to a terminal with a reference voltage; and
a first coupling capacitor and a second coupling capacitor,
wherein the first coupling capacitor, the first component, the second component, and the second coupling capacitor are looped in series between terminals that are not connected to the reference voltage of the first and second oscillator coil,
wherein the frequency control signal is applied to a terminal of the first and second component, and
wherein the compensation signal is applied to a terminal that is opposite the terminal of the first and second component.

6. The voltage-controlled oscillator according to claim 5, wherein a first decoupling resistor is looped between the compensation signal and the terminal opposite the connection point of the first component, and wherein a second decoupling resistor is looped between the compensation signal and the terminal opposite the connection point of the second component.

7. The voltage-controlled oscillator according to claim 1, further comprising an undamping circuit.

8. The voltage-controlled oscillator according to claim 1, wherein the oscillator operating frequency is in the range of 2 GHz to 7 GHz.

9. A temperature detecting unit for a voltage-controlled oscillator, the temperature detecting unit comprising:
a temperature sensor;
a differential amplifier having a first terminal connected to the temperature sensor and an output for providing a temperature signal;
a buffer unit having an input connected to the temperature sensor and an output being connected to a second terminal of the differential amplifier; and
a control unit for controlling the buffer unit so that a temperature sensor value is temporarily stored at a start of a measuring interval.

10. The temperature detecting unit according to claim 9, wherein the temperature sensor comprises a bipolar semiconductor.

11. The temperature detecting unit according to claim 9, wherein the temperature sensor comprises at least one p-n diode.

12. The temperature detecting unit according to claim 9, wherein the control unit temporarily stores the temperature sensor value depending on an operating state.

13. The voltage-controlled oscillator according to claim 1, wherein the voltage-controlled oscillator is electrically coupled to a temperature detecting unit for detecting a temperature, wherein the frequency drift compensation unit compensates for the oscillator frequency drift on the basis of the detected temperature.

14. The voltage-controlled oscillator according to claim 13, wherein the voltage-controlled oscillator is an ISM transceiver.
